(19) United States
(12) Patent Application Publication
(10) Pub. No.: US 2025/0308921 A1
(43) Pub. Date: Oct. 2, 2025

(54) SUBSTRATE PROCESSING APPARATUS AND SUBSTRATE PROCESSING METHOD

(71) Applicant: PSK INC., Gyeonggi-do (KR)

(72) Inventors: A Ram KIM, Gyeonggi-do (KR); Min Jae JEONG, Gyeonggi-do (KR)

(21) Appl. No.: 19/097,633

(22) Filed: Apr. 1, 2025

(30) Foreign Application Priority Data
Apr. 2, 2024 (KR) 10-2024-0044902

(51) Int. Cl. H01L 21/311; H01J 37/32

(52) U.S. Cl. CPC H01L 21/31116; H01J 37/32357; H01J 2237/0047

(57) ABSTRACT

The inventive concept provides an apparatus for processing a substrate. The substrate processing apparatus may include a treatment chamber having a treatment space for processing a substrate therein; a support unit for supporting a substrate in the treatment space; a plasma generation chamber provided outside the treatment chamber and having a plasma generation space for generating plasma from treatment gas; a baffle disposed between the treatment space and the plasma generation space; and an ionization device for discharging a charge on a substrate supported on the support unit to remove a residual charge on the substrate.

### CROSS-REFERENCE TO RELATED APPLICATIONS

This application claims priority to and the benefit of Korean Patent Application No. 10-2024-0044902 filed in the Korean Intellectual Property Office on Apr. 2, 2024, the entire contents of which are incorporated herein by reference.

### TECHNICAL FIELD

The present invention relates to a substrate processing apparatus and a substrate processing method, and more particularly to an apparatus and method of processing a substrate by using plasma.

### BACKGROUND ART

Plasma refers to an ionized gas state formed of ions, radicals, electrons, and the like, and is generated by a very high temperature, strong electric fields, or RF electromagnetic fields. Semiconductor device manufacturing processes include the ashing or etching process, which uses plasma to remove films from substrates, such as wafers.

In removing the film on the substrate, among the ions, electrons, and radicals contained in the plasma, radicals may be utilized mainly. In this case, a grounded baffle is provided between the plasma generation space where the plasma is generated and the treatment space where the substrate is treated, and the radicals in the plasma are fed into the treatment space through the holes formed in the baffle.

The power source also applies an RF signal to the lower electrodes of the substrate support unit that supports the substrate, creating an electric field in the treatment space. After the plasma treatment of the substrate is finished, strong attraction force is formed between the substrate and the lower electrode due to the accumulation of negative charges on the surface of the substrate. When the substrate is forcibly lifted in this state, the substrate may be damaged due to the attraction between the substrate and the substrate support unit.

### SUMMARY OF THE INVENTION

The present invention has been made in an effort to provide a substrate processing apparatus and a substrate processing method, which are capable of efficiently processing a substrate.

The present invention has also been made in an effort to provide a substrate processing apparatus and a substrate processing method, which are capable of rapidly discharging an accumulated charge on a substrate after processing the substrate with plasma.

The present invention has also been made in an effort to provide a substrate processing apparatus and a substrate processing method, which may minimize damage to a substrate when the substrate is lifted from a substrate support unit.

The inventive concept provides an apparatus for processing a substrate. The substrate processing apparatus may include a treatment chamber having a treatment space for processing a substrate therein; a support unit for supporting a substrate in the treatment space; a plasma generation chamber provided outside the treatment chamber and having a plasma generation space for generating plasma from treatment gas; a baffle disposed between the treatment space and the plasma generation space; and an ionization device for discharging a charge on a substrate supported on the support unit to remove a residual charge on the substrate.

According to the exemplary embodiment, the baffle may be grounded.

According to the exemplary embodiment, the ionization device may be provided in the treatment chamber.

According to the exemplary embodiment, the ionization device may be coupled to a bottom of the baffle.

According to the exemplary embodiment, the apparatus may further include a high frequency power source for applying high frequency power to the support unit.

According to the exemplary embodiment, the ionization device includes an ultraviolet lamp.

According to the exemplary embodiment, the apparatus may further include a controller, wherein the controller controls the apparatus to perform: a processing operation of plasma processing the substrate by supplying plasma to the substrate supported on the support unit; a substrate residual charge removing operation of, upon completion of the processing operation, stopping the supply of the plasma and removing residual charges accumulated on the substrate; and an operation of, upon completion of the substrate residual charge removing operation, lifting the substrate from the support unit.

The inventive concept provides a method of processing a substrate. The method may include a loading operation of placing a substrate on a support unit provided in a treatment space; a processing operation of, after the loading operation, plasma processing the substrate by providing plasma to the treatment space; a residual charge removing operation of, after the processing operation, removing residual charges on the substrate; and an unloading operation of, after the residual charge removing operation, lifting the substrate from the support unit.

According to the exemplary embodiment, the plasma treatment may include removing a thin film on the substrate by using plasma.

According to the exemplary embodiment, the thin film may be a hard mask.

According to the exemplary embodiment, the support unit may include an electrostatic chuck, the loading operation is an operation of chucking the substrate onto the electrostatic chuck, and the unloading operation is an operation of dechucking the substrate from the electrostatic chuck.

According to the exemplary embodiment, the plasma may be generated in a plasma generation space provided outside the treatment space, and the plasma generated in the plasma generation space enters the treatment space through a baffle.

According to the exemplary embodiment, the residual charge removing operation may be performed by supplying ions to the substrate.

According to the exemplary embodiment, the supply of the ions may include generating ions by irradiating the treatment space with ultraviolet light.

The inventive concept provides an apparatus for processing a substrate. The substrate processing apparatus may include a treatment chamber having a treatment space for processing a substrate therein; a support unit including an electrostatic chuck for supporting the substrate in the treatment space; a plasma generation chamber having a plasma generation space for generating plasma from treatment gas; a source unit for generating plasma in the plasma generation space; a power unit for applying high frequency power to the support unit; a baffle disposed between the treatment space and the plasma generation space and grounded; and an ionization device for discharging a charge on a substrate supported on the support unit to remove residual charges on the substrate, wherein the treatment chamber is located below the plasma generation chamber, and the ionization device may be coupled to a bottom of the baffle and emits ultraviolet light to generate ions.

According to the exemplary embodiment, the apparatus may further include a controller, wherein the controller controls the apparatus to perform: a processing operation of plasma processing the substrate by supplying plasma to the substrate supported on the support unit; a residual charge removing operation of, upon completion of the processing operation, stopping the supply of the plasma and removing residual charges accumulated on the substrate; and an operation of, upon completion of the residual charge removing operation, lifting the substrate from the support unit.

According to the exemplary embodiment of the present invention, the substrate may be treated efficiently.

Further, according to the exemplary embodiment of the present invention, the charge accumulated on the substrate may be quickly discharged after processing the substrate with plasma.

Further, according to the exemplary embodiment of the present invention, damage to the substrate may be minimized when the substrate is lifted from the substrate support unit.

### BRIEF DESCRIPTION OF THE DRAWINGS

FIG. 1 is a diagram illustrating a photoresist film formed on a substrate.

FIG. 2 is a diagram illustrating a hardmask film formed on a substrate.

FIG. 3 is a diagram illustrating a substrate processing apparatus according to an exemplary embodiment of the present invention.

FIGS. 4 and 5 are top plan views schematically illustrating an exemplary embodiment of a baffle of FIG. 3, respectively.

FIG. 6 is a flow chart illustrating an exemplary embodiment of a method of processing a substrate by using the substrate processing apparatus of FIG. 3.

FIG. 7 is a diagram schematically illustrating the substrate processing apparatus of FIG. 3 performing a processing operation of FIG. 6.

FIG. 8 is a diagram schematically illustrating the substrate processing apparatus of FIG. 3 performing a residual charge removing operation of FIG. 6.

FIG. 9 is a diagram illustrating a substrate processing apparatus according to another exemplary embodiment of the present invention.

FIG. 10 is a diagram illustrating a substrate processing apparatus according to another exemplary embodiment of the present invention.

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

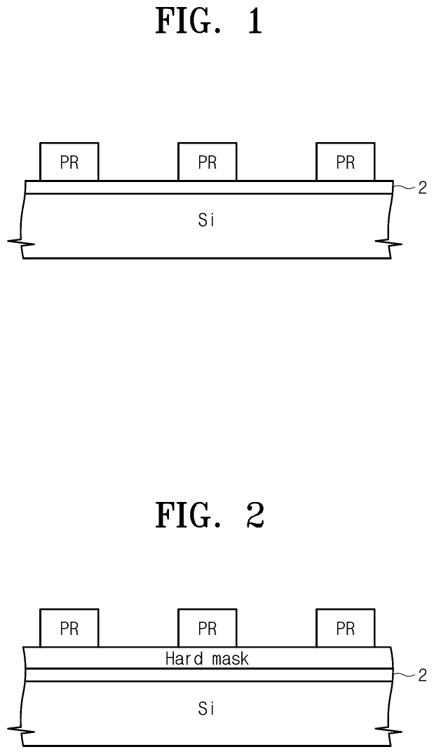

Hereinafter, with reference to FIGS. 1 to 8, a substrate processing apparatus and a substrate processing method according to an exemplary embodiment of the present invention will be described in detail. The substrate W described hereinafter may be a wafer. Processing the substrate W may mean not only processing the substrate W but also removing a film or the like formed on the substrate W.

In one example, the substrate processing apparatus may etch a thin film on the substrate W. The thin film may be a polysilicon film, a silicon oxide film, a silicon nitride film, and various other types of films. Further, the thin film may be a natural oxide film or a chemically generated oxide film.

FIG. 1 is a diagram illustrating a photoresist film formed on a thin film 2 on a substrate, and FIG. 2 is a diagram illustrating a hardmask film formed on a thin film 2 on a substrate.

A substrate to be treated as described herein may have a first film (e.g., a photoresist thin film) formed on the substrate, as illustrated in FIG. 1, and a second film (e.g., a hardmask thin film) formed on the substrate, as illustrated in FIG. 2. In FIG. 2, both the first film (photoresist thin film) and the second film (hardmask thin film) are formed on the substrate, but in some cases, only the second film (hardmask thin film) between the first film (photoresist thin film) and the second film (hardmask thin film) may be formed on the substrate. The hardmask film may be an Amorphous Carbon Layer (ACL). The Amorphous Carbon Layer (ACL) may be a Boron doped Amorphous Carbon Layer (BACL).

The substrate processing method described herein may be a manufacturing method for manufacturing a semiconductor device. The substrate processing method may include at least one process among a number of processes required to manufacture a semiconductor device.

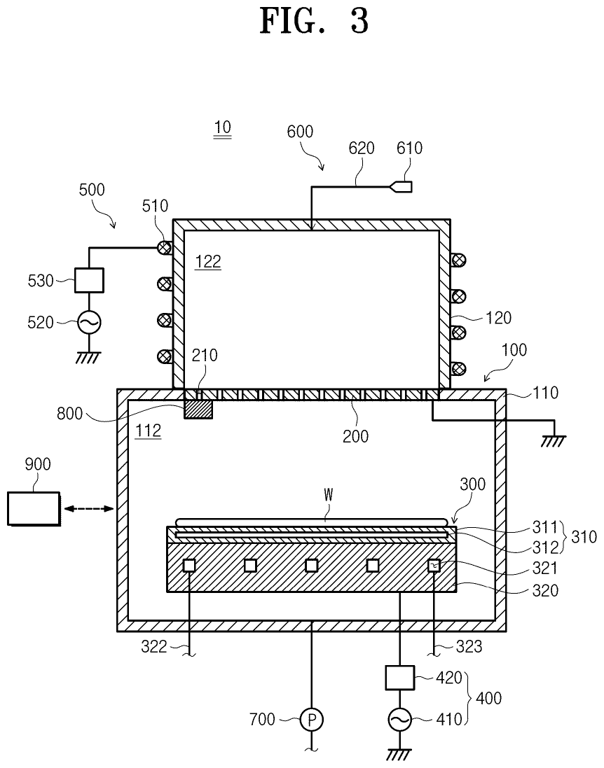

FIG. 3 is a diagram illustrating a substrate processing apparatus according to an exemplary embodiment of the present invention.

Referring to FIG. 3, a substrate processing apparatus 10 according to an exemplary embodiment of the present invention may include a chamber 100, a baffle 200, a support unit 300, a lower power unit 400, a source unit 500, a gas supply unit 600, an exhaust device 700, an ionization device 800, and a controller 900.

The chamber 100 may include a treatment chamber 110 defining a treatment space 112, and a plasma generation chamber 120 defining a plasma generation space 122. The plasma generation chamber 120 may be provided outside of the treatment chamber 110. The treatment chamber 110 and the plasma generation chamber 120 may be arranged along an upward and downward direction. The treatment chamber 110 may be installed below the plasma generation chamber 120. In the treatment space 112, a treatment process for the substrate W may be performed, and in the plasma generation space 122, the source unit 500 which is to be described below may generate plasma from process gas supplied by the gas supply unit 600 described later.

The treatment chamber 110 may have an inlet/outlet not illustrated. The substrate W may be brought into, or taken out of, the treatment chamber 112 via the inlet/outlet. The inlet/outlet may be selectively opened and closed by a door.

The plasma generation chamber 120 may provide the plasma generation space 122 in which the plasma P described hereinafter is generated. Although plasma P may also be generated in the treatment space 112 by the lower power unit 400, the plasma P provided for processing the substrate W may be generated in the plasma generation space 122.

The plasma generation space 122 may be in fluid communication with the treatment space 112. The plasma P generated in the plasma generation space 122 may flow from the plasma generation space 122 to the treatment space 112.

The gas supply unit 600 described later may supply the process gas to the plasma generation space 122, and the source unit 400 may excite the process gas to generate the plasma P.

The baffle 200 may be installed between the treatment space 112 and the plasma generation space 122. The baffle 200 may be installed between the treatment space 112 and the plasma generation space 122 to compartmentalize the two spaces. The baffle 200 may define the treatment space 112 together with the treatment chamber 110. Further, the baffle 200 may define the plasma generation space 122 in conjunction with the plasma generation chamber 120.

The baffle 200 may be grounded. The baffle 200 may have a plate shape. A plurality of holes 210 may be formed in the baffle 200. Through the plurality of holes 210 formed in the baffle 200, the treatment space 112 and the plasma generation space 122 may be connected to each other. Plasma generated in the plasma generation space 122 may enter the treatment space 112 through the holes 210 formed in the baffle 200.

The baffle 200 may be grounded. The baffle 200 may be electrically grounded to the grounded chamber 100.

The plasma generated in the plasma generation space 122 may include ions and radicals. In the process in which the plasma generated in the plasma generation space 122 enters the treatment space 112 through the holes 210 formed in the baffle 200, at least some of the ions contained in the plasma may be trapped by the grounded baffle 200.

The baffle 200 may be made of a material including a metal. The baffle 200 may be made of a conductive material.

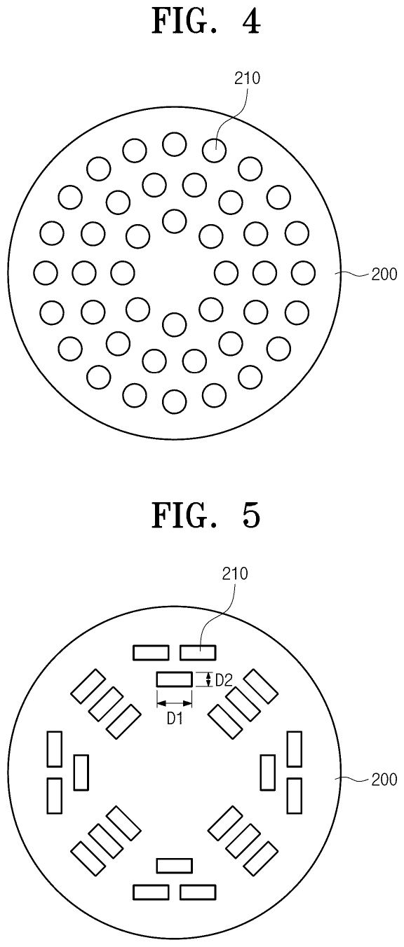

FIGS. 4 and 5 are plan views schematically illustrating an exemplary embodiment of the baffle of FIG. 3.

Referring to FIG. 4, a plurality of holes 210 may be formed in the baffle 200. The holes 210 may be formed in the baffle 200 at regular intervals spaced apart along a circumferential direction of the baffle 200.

The holes 210 formed in the baffle 200 may have a substantially circular shape, as illustrated in FIG. 4. The diameter of the holes 210 may be varied depending on the proportion of radicals that need to be transferred to the substrate W. Alternatively, as illustrated in FIG. 5, the holes 210 may have a rectangular shape having a first width D1 and a second width D2. The first width D1 and the second width D2 may be varied depending on the proportion of radicals to be transferred to the substrate W, etc. In other words, an operator may optionally install the baffle 200 formed with the holes 210 having various sizes, shapes, and the like in the substrate processing apparatus 10, depending on the required values for processing the substrate W.

Referring again to FIG. 3, the support unit 300 may support the substrate W. The support unit 300 may support the substrate W in the treatment space 112. The support unit 300 may include an electrostatic chuck 310, and a lower electrode 320.

The electrostatic chuck 310 may chuck the substrate W. The electrostatic chuck 310 may have a dielectric plate 311 and an electrostatic electrode 312. The dielectric plate 311 may provide a seating surface on which the substrate W is placed. The dielectric plate 311 may have a capacitive electrode 312 buried within the dielectric plate 311. The electrostatic electrode 312 may be applied with power from a chucking power source (not illustrated), which may be a DC power source, to generate electrostatic force for chucking the substrate W.

The lower electrode 320 may be disposed below the electrostatic chuck 310. The lower electrode 320 may be made of a material including metal. The lower electrode 320 may be connected to the lower electrode unit 300, which will be described later. A flow path 321 may be formed in the lower electrode 320. A cooling fluid, such as a coolant or cooling gas, may flow in the flow path 321. A fluid supply line 322 may be connected to one end of the flow path 321 to supply cooling fluid, and a fluid recovery line 323 may be connected to the other end to recover cooling fluid.

The lower power unit 400 may apply high frequency RF power to the lower electrode 320. The lower power unit 400 may apply bias power to the lower electrode 320. The lower power unit 400 may include a second power source 410 and a second matcher 420. The second power source 410 may be a bias power source. The second power source 410 may apply second power having a second frequency to the lower electrode 320. The second matcher 420 may perform impedance matching to ensure that power from the second power source 410 is effectively delivered to the lower electrode 320.

RF power applied by the lower power unit 400 may control the flow of plasma P including at least one of ions, electrons, and radicals flowing into the treatment space 112 to improve treatment efficiency for the substrate W. Additionally, RF power applied by the lower power unit 400 may excite process gas supplied to the treatment space 112 to generate the plasma P.

The source unit 500 may generate the plasma P in the plasma generation space 122. The source unit 500 may generate plasma P in the plasma generation space 122 by exciting process gas supplied by the gas supply unit 600 described later.

The source unit 500 may include a coil 510, a first power source 520, and a first matcher 530.

The coil 510 may be configured to surround the plasma generation chamber 120. The coil 510 may be provided on an exterior side of the plasma generation chamber 120. The number of windings of the coil 510 wrapped around the plasma generation chamber 120 may vary depending on the strength of the electric field required in the treatment space 122. The coil 510 may receive power from the first power source 520 and may create an electric field in the plasma generation space 122. The electric field formed in the plasma generation space 122 may excite the process gas to generate plasma P. The coil 510 may also be referred to as the top electrode.

The first power source 520 may apply RF power to the coil 510. The first power source 520 may apply first power to the coil 510 having a first frequency that is a different frequency from the second frequency described above. The first frequency may be a higher frequency than the second frequency. The first power source 520 may be a source power source. The first matcher 530 may perform impedance matching to ensure that power from the first power source 520 is effectively delivered to the coil 510.

Although not illustrated, the substrate processing apparatus 10 may further include an impedance control unit, and the impedance control unit may be configured to form a resonant circuit with respect to the first frequency and the second frequency. The impedance control unit may include a sensor S, an inductor L1, a first capacitor C1, and a second capacitor C2.

The gas supply unit 600 may supply process gas to the plasma generation space 122 and/or the treatment space 112. The gas supply unit 600 may include a gas supply source 610, and a gas supply line 620. The gas supply source 610 may supply and/or store process gas. The gas supply line 620 may be connected to an upper portion of the plasma generation chamber 120. The gas supply source 610 may supply process gas to the plasma generation space 122 via the gas supply line 620.

A majority of the process gas supplied to the plasma generation space 122 may be excited to the plasma P state by the source unit 500. A portion of the process gas may not be excited in the plasma generation space 122 and may enter the treatment space 112. The process gas entering treatment space 112 may be excited to the plasma P state by the lower power unit 400.

The exhaust device 700 may exhaust the treatment space 112. The exhaust device 700 may be connected to a lower portion of the treatment chamber 110. The exhaust device 700 may be a pump. An exhaust hole (not illustrated) may be formed in the lower portion of the treatment chamber 110, and the exhaust device 700 may exhaust the treatment space 112 through the exhaust hole. The exhaust device 700 may depressurize the treatment space 112. Process by-products or impurities in the treatment space 112 may be discharged to the outside of the treatment chamber 110 through the exhaust device. The exhaust device 700 may depressurize the treatment space 112, creating a downdraft flow in the plasma generation space 122 and/or the treatment space 112. The exhaust device 700 may help the pressure in the treatment space 112 reach a pressure close to a vacuum while the process is being performed.

The ionization device 800 generates ions to discharge the accumulated charge on the substrate W supported on the support unit 300. The ionization device 800 may neutralize the substrate W by discharging the charge on the substrate W. The ionization device 800 may generate positive ions to neutralize the substrate W in which negative charges are accumulated. The ionization device 800 may be installed in the treatment space 112. The ionization device 800 may be installed at the bottom of the baffle 200. The ionization device 800 may be coupled to the baffle 200.

The ionization device 800 may include an ultraviolet (UV) lamp. The ionization device 800 may be a device that generates ions by irradiating ultraviolet light. The ionization device 800 may be a UV/VUV ionizer. The ionization device 800 may be a nozzle type, gun type, or blower type ionizer.

The controller 900 may control the substrate processing apparatus 10. The controller 900 may control configurations of the substrate processing apparatus 10. For example, the controller 900 may generate control signals to control the support unit 300, the lower power unit 400, the source unit 500, the gas supply unit 600, the exhaust device 700, and the ionization device 800.

The controller 900 may include a process controller formed of a microprocessor (computer) that executes the control of the substrate processing apparatus 10, a user interface formed of a keyboard in which an operator performs a command input operation or the like in order to manage the substrate processing apparatus 10, a display for visualizing and displaying an operation situation of the substrate processing apparatus 10, and the like, and a storage unit storing a control program for executing the process executed in the substrate processing apparatus 10 under the control of the process controller or a program, that is, a processing recipe, for executing the process in each component according to various data and processing conditions. Further, the user interface and the storage unit may be connected to the process controller. The treating recipe may be stored in a storage medium in the storage unit, and the storage medium may be a hard disk, and may also be a portable disk, such as a CD-ROM or a DVD, or a semiconductor memory, such as a flash memory.

The substrate processing apparatus 10 may generate plasma P to process the substrate W, for example to perform an etch process or a strip process to remove a film formed on the substrate W.

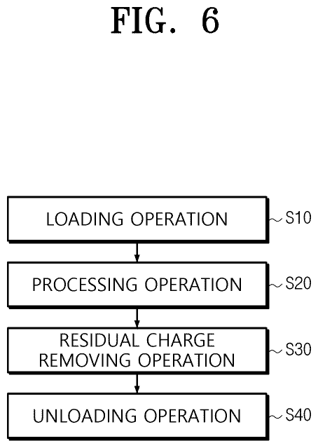

FIG. 6 is a flow chart illustrating an exemplary embodiment of a method of processing a substrate by using the substrate processing apparatus of FIG. 3.

Referring to FIGS. and 6, a method of processing a substrate according to an exemplary embodiment of the present invention may include a loading operation S10, a processing operation S10, a residual charge removing operation S30, and an unloading operation S40.

In the loading operation S10, the substrate W may be loaded into the treatment space 112 by a transfer robot (not illustrated). The substrate W loaded into the treatment space may be placed on the support unit 300. The electrostatic chuck 310 may chuck the substrate W by generating electrostatic force.

When the loading operation S10 ends and the substrate W is loaded onto the support unit 300, a processing operation S20 is performed.

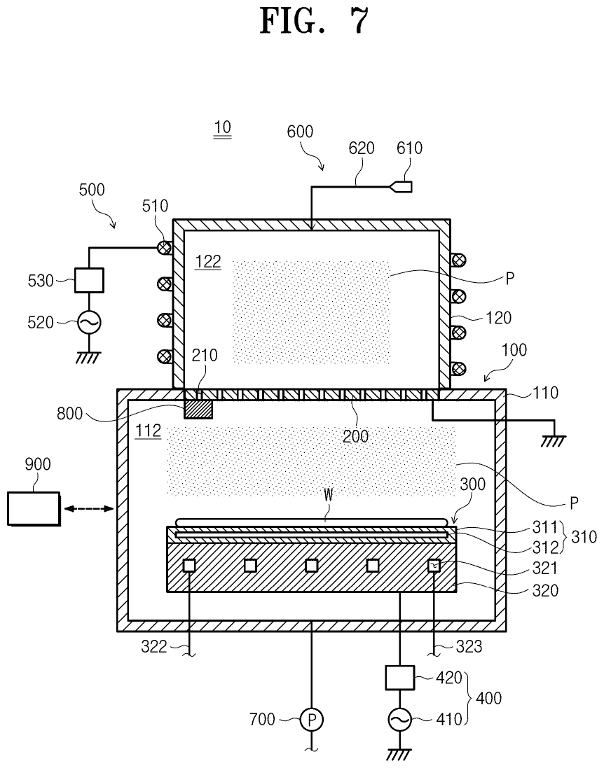

In the processing operation S20, the substrate W is treated by supplying plasma P to the treatment space 112. FIG. 7 is a diagram schematically illustrating the substrate processing apparatus of FIG. 3 performing the processing operation of FIG. 6.

Referring to FIGS. 6 and 7, the gas supply unit 600 may supply process gas to the plasma generation space 122, and the source unit 500 may excite the process gas to generate plasma P. The first power source 520 of the source unit 500 may apply second power having a first frequency (e.g., 13.56 MHz) to the coil 510. The plasma P generated in the plasma generation space 122 may include ions, electrons, and radicals. Of these, radicals may generally pass through the baffle 200 and enter the treatment space 112. Additionally, process gas that is not excited to the plasma P state in the plasma generation space 122 may pass through the baffle 200 and enter the treatment space 112.

Radicals entering the treatment space 112 may remove the film on the substrate W. In addition, the process gas entering the treatment space 112 may be partially excited into plasma P by an electric field formed by the second power source 410, which is a bias power source. The second power source 410 may apply second power having a second frequency (e.g., 2 MHz) to the lower electrode 320.

The plasma P removes a film on the substrate W. As described above, the film on the substrate W may include at least one of a first film (photoresist thin film) or a second film (hardmask thin film), as illustrated in FIGS. 1 and 2. In the treatment space 112, some ions may be present that have passed through the baffle 200 without being trapped by the baffle 200 in the process in which plasma generated in the plasma generation space 122 enters the treatment space 112 through the holes 210 formed in the baffle 200. In addition, some ions may be present that are generated in the process in which process gas entering the treatment space 112 is excited into plasma P by an electric field formed by the second power source 410, which is a bias power source. The ion energy incident on the substrate may help to remove the second film on the substrate (e.g., a hard disc thin film) that is relatively corrosion resistant.

During the treatment of the substrate using the plasma in the processing operation S20, a negative charge is accumulated on the substrate W and a negative voltage is applied because the mobility of electrons in the treatment space 112 is faster than that of ions. The negative voltage applied at this time is called a DC self bias.

The processing operation S20 ends, the gas supply unit 600 stops supplying process gas, and the first power source 520 and the second power source 410 are turned off to stop generating and supplying plasma. Even though no RF signal is flowing to the coil 510 and the lower electrode 320, strong attractive force due to a voltage difference is formed between the substrate W and the lower electrode 320 because of the accumulation of negative charge on the substrate W. If the substrate W is unloaded from the support unit 300 immediately after the end of the processing operation S20, the substrate may be damaged due to the attraction between the substrate W and the lower electrode 320 of the support unit 300. Therefore, after the processing operation S20, a residual charge removing operation S30 is performed to remove the residual charge accumulated on the substrate W and neutralize the substrate.

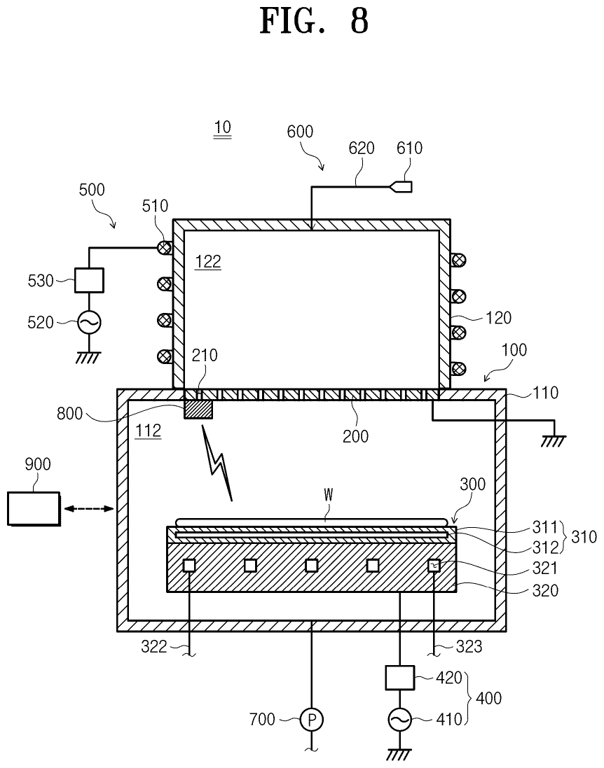

FIG. 8 is a diagram schematically illustrating the substrate processing apparatus of FIG. 3 performing the residual charge removing operation of FIG. 6.

Referring to FIGS. 6 and 8, in the residual charge removing operation S30, the ionization device 800 may be operated to discharge the accumulated charge on the substrate W. Specifically, the ionization device 800 may supply positive ions to the treatment space 112, and the positive ions may neutralize the substrate W to rapidly discharge the charge on the substrate W.

When the residual charge removing operation S30 ends, the unloading operation S40 is performed. In the unloading operation S40, the electrostatic chuck 310 may dechuck the substrate W, and the substrate W may be lifted from the support unit 300 and unloaded from the treatment space 112.

As described above, by performing the residual charge removing operation S30, which discharges the charge accumulated on the substrate W after the processing operation S20 and prior to unloading the substrate W from the support unit 300, via the ionization device 800, the damage to the substrate W may be minimized due to the electrical attraction between the substrate W and the electrostatic chuck 310 during the unloading of the substrate W.

In the examples described above, the present invention has been described based on the case where the upper electrode is the coil 510, but is not limited thereto. For example, the upper electrode may be provided as an electrode plate having a plate shape.

In the exemplary embodiments described above, not only the plasma generation space 122, but also the treatment space 112 is illustrated and described as being excited with plasma P by an electric field formed by the second power source 410, which is a bias power source. For example, the plasma P may be excited only in the plasma generation space 122 and enter the treatment space 112 through the baffle 200.

In the exemplary embodiment described above, the ionization deice 800 is illustrated and described as being coupled to the bottom of the baffle 200, but the present invention is not limited thereto. The ionization device 800 may be provided at other locations within the treatment chamber 110 where it may supply ions to the substrate W and discharge the substrate W.

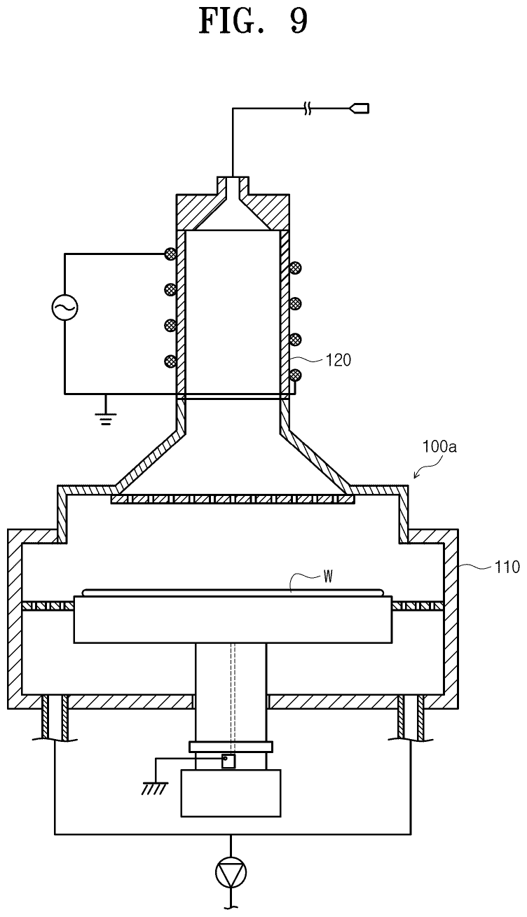

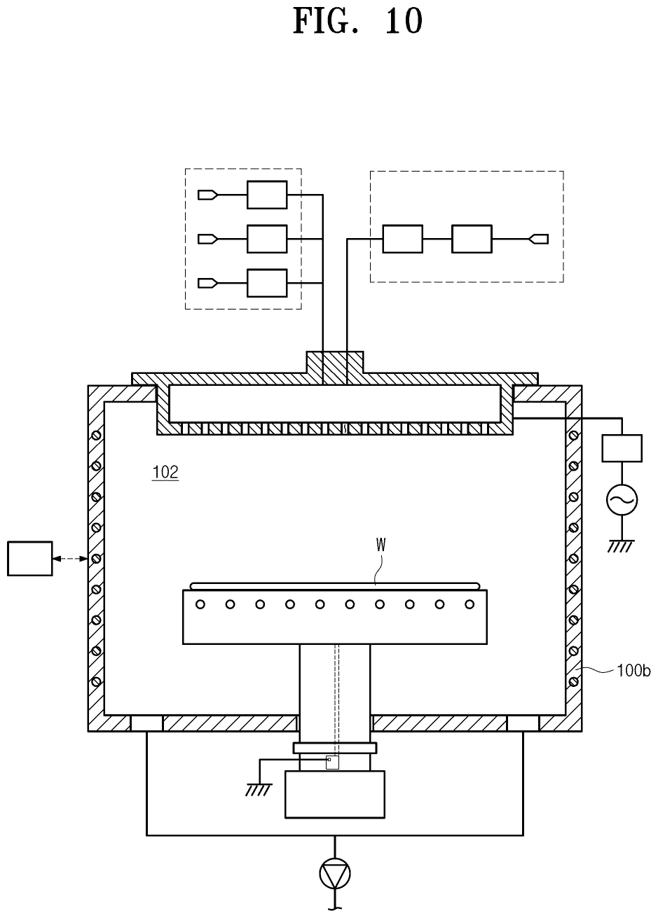

In the exemplary embodiment described above, the chamber 100 is illustrated and described as including the treatment chamber 110 and the plasma generation chamber 120, with the baffle 200 installed between the treatment chamber 112 and the plasma generation chamber 122, but the present invention is not limited thereto. The chamber 100 may be applied to a variety of devices that treat the substrate W with plasma. For example, a chamber 100a, as illustrated in FIG. 9, may be provided in a form that includes an adapter configuration which is the space in which plasma flows between the treatment chamber 110 and the plasma generation chamber 120, and a chamber 100b, as illustrated in FIG. 10, may be provided in a form in which the treatment chamber and the plasma generation chamber are provided in the same space, such that plasma is generated in the treatment space 102.

It should be understood that exemplary embodiments have been disclosed herein, and other modifications may be possible. Individual elements or features of a particular exemplary embodiment are generally not limited to the particular exemplary embodiment, but may be interchangeable and used in selected exemplary embodiments, if applicable, if not specifically illustrated or described. Such modifications should not be considered outside the spirit and scope of the present disclosure, and all such modifications obvious to those skilled in the art are intended to be included within the scope of the following claims.

The effects of the inventive concept are not limited to the above-mentioned effects, and the unmentioned effects can be clearly understood by those skilled in the art to which the inventive concept pertains from the specification and the accompanying drawings.

Although the preferred embodiment of the inventive concept has been illustrated and described until now, the inventive concept is not limited to the above-described specific embodiment, and it is noted that an ordinary person in the art, to which the inventive concept pertains, may be variously carry out the inventive concept without departing from the essence of the inventive concept claimed in the claims and the modifications should not be construed separately from the technical spirit or prospect of the inventive concept.

What is claimed is:

1. An apparatus for processing a substrate, the apparatus comprising:
a treatment chamber having a treatment space for processing a substrate therein;
a support unit for supporting a substrate in the treatment space;
a plasma generation chamber provided outside the treatment chamber and having a plasma generation space for generating plasma from treatment gas;
a baffle disposed between the treatment space and the plasma generation space; and
an ionization device for discharging a charge on a substrate supported on the support unit to remove a residual charge on the substrate.

2. The apparatus of claim 1, wherein the baffle is grounded.

3. The apparatus of claim 1, wherein the ionization device is provided in the treatment chamber.

4. The apparatus of claim 1, wherein the ionization device is coupled to a bottom of the baffle.

5. The apparatus of claim 1, further comprising:
a high frequency power source for applying high frequency power to the support unit.

6. The apparatus of claim 1, wherein the ionization device includes an ultraviolet lamp.

7. The apparatus of claim 1, further comprising:
a controller,
wherein the controller controls the apparatus to perform:
a processing operation of plasma processing the substrate by supplying plasma to the substrate supported on the support unit;
a substrate residual charge removing operation of, upon completion of the processing operation, stopping the supply of the plasma and removing residual charges accumulated on the substrate; and
an operation of, upon completion of the substrate residual charge removing operation, lifting the substrate from the support unit.

8. A method of processing a substrate, the method comprising:
a loading operation of placing a substrate on a support unit provided in a treatment space;
a processing operation of, after the loading operation, plasma processing the substrate by providing plasma to the treatment space;
a residual charge removing operation of, after the processing operation, removing residual charges on the substrate; and
an unloading operation of, after the residual charge removing operation, lifting the substrate from the support unit.

9. The method of claim 8, wherein the plasma treatment includes removing a thin film on the substrate by using plasma.

10. The method of claim 9, wherein the thin film is a hard mask.

11. The method of claim 8, wherein the support unit includes an electrostatic chuck,
the loading operation is an operation of chucking the substrate onto the electrostatic chuck, and
the unloading operation is an operation of dechucking the substrate from the electrostatic chuck.

12. The method of claim 8, wherein the plasma is generated in a plasma generation space provided outside the treatment space, and
the plasma generated in the plasma generation space enters the treatment space through a baffle.

13. The method of claim 8, wherein the residual charge removing operation is performed by supplying ions to the substrate.

14. The method of claim 13, wherein the supply of the ions includes generating ions by irradiating the treatment space with ultraviolet light.

15. An apparatus for processing a substrate, the apparatus comprising:
a treatment chamber having a treatment space for processing a substrate therein;
a support unit including an electrostatic chuck for supporting the substrate in the treatment space;
a plasma generation chamber having a plasma generation space for generating plasma from treatment gas;
a source unit for generating plasma in the plasma generation space;
a power unit for applying high frequency power to the support unit;
a baffle disposed between the treatment space and the plasma generation space and grounded; and
an ionization device for discharging a charge on a substrate supported on the support unit to remove residual charges on the substrate,
wherein the treatment chamber is located below the plasma generation chamber, and
the ionization device is coupled to a bottom of the baffle and emits ultraviolet light to generate ions.

16. The apparatus of claim 15, further comprising:
a controller,
wherein the controller controls the apparatus to perform:
a processing operation of plasma processing the substrate by supplying plasma to the substrate supported on the support unit;
a residual charge removing operation of, upon completion of the processing operation, stopping the supply of the plasma and removing residual charges accumulated on the substrate; and
an operation of, upon completion of the residual charge removing operation, lifting the substrate from the support unit.
